(19) United States
(12) Patent Application Publication
(10) Pub. No.: US 2026/0068742 A1
(43) Pub. Date: Mar. 5, 2026

(54) SEMICONDUCTOR DEVICE AND METHOD OF MANUFACTURING SEMICONDUCTOR DEVICE

(71) Applicant: FUJI ELECTRIC CO., LTD., Kawasaki-shi (JP)

(72) Inventor: Yuhei NISHIDA, Matsumoto-city (JP)

(73) Assignee: FUJI ELECTRIC CO., LTD., Kawasaki-shi (JP)

(21) Appl. No.: 19/279,806

(22) Filed: Jul. 24, 2025

(30) Foreign Application Priority Data
Sep. 4, 2024 (JP) 2024-151926

(51) Int. Cl. H01L 23/047; H01L 21/48; H01L 23/00; H01L 23/373

(52) U.S. Cl. CPC H01L 23/047

(57) ABSTRACT

A semiconductor apparatus, including: a conductive pattern; and a terminal that includes a bonding portion that has a rear surface bonded to the conductive pattern, a rising portion extending upward from the bonding portion, and a joining portion that joins the bonding portion and the rising portion without being bonded to the conductive pattern. The bonding portion has, on a front surface thereof, a plurality of rows of indentations, the indentations in each row being aligned in a first direction up to a boundary between the bonding portion and the joining portion. Each indentation has a recess. Any two of the recesses that are adjacent in a second direction perpendicular to the first direction are disposed at positions that are displaced from each other in the first direction. Each recess has a deepest point. The deepest points of the recesses are positioned away from the boundary.

### CROSS-REFERENCE TO RELATED APPLICATION

This application is based upon and claims the benefit of priority of the prior Japanese Patent Application No. 2024-151926, filed on Sep. 4, 2024, the entire contents of which are incorporated herein by reference.

### BACKGROUND OF THE INVENTION

### 1. Field of the Invention

The embodiment discussed herein relates to a semiconductor device and a method of manufacturing a semiconductor device.

### 2. Background of the Related Art

In a semiconductor device, first protrusions and second protrusions are arranged in a plurality of rows on a pressing portion, and when pressed onto a flat portion of a metal plate, the first protrusions cut into a neck portion-side of the flat portion (see Japanese Laid-open Patent Publication No. 2014-179435). In another configuration, a bonding portion of a terminal to be bonded to a wiring portion is wider than an intermediate part of the terminal (see Japanese Laid-open Patent Publication No. 2022-189515). In another configuration, a connection terminal includes a main body part that extends toward a main terminal and a conductive joining part that is joined to the main body part, with the joining part having a larger cross-sectional area in a direction perpendicular to a current path than the part of the main body part to which the joining part is joined (see Japanese Laid-open Patent Publication No. 2023-168849). In another semiconductor device, a curved surface portion is formed on a flat surface portion, where a plurality of protrusions are formed, so as to be curved toward a length direction while sharing a tangent line with the flat surface portion (see Japanese Laid-open Patent Publication No. 2012-124247). Another semiconductor device has a plurality of protrusions, which are concave on a conductive layer-side and convex on a buffer layer-side, formed in a bonding region for bonding to a surface electrode (see Japanese Laid-open Patent Publication No. 2016-139635).

Another configuration includes a bonding region, where a connected part of a lead frame is bonded to a wiring pattern, and end non-bonding regions, which are formed on both sides of the bonding region and face the wiring pattern with gaps in between (see Japanese Laid-open Patent Publication No. 2012-039018). Another semiconductor device includes a porous member, which is made of metal and disposed on an electrode, and plate-shaped wiring disposed on the porous member (see Japanese Laid-open Patent Publication No. 2016-111083). In another configuration, an electrode terminal and a bonded object are ultrasonically bonded to a bonding surface provided for bonding purposes, with the electrode terminal including a hollow portion that passes through the electrode terminal and is surrounded by the bonding surface (see Japanese Laid-open Patent Publication No. 2016-096172). In another semiconductor device, out of a bonding surface of an electrode terminal, a part that cuts into a conductor pattern is inclined outward toward the main surface of the conductor pattern (see Japanese Laid-open Patent Publication No. 2014-183157).

### SUMMARY OF THE INVENTION

According to aspect of the present disclosure, there is provided a semiconductor apparatus, including: a conductive pattern; and a terminal, including: a bonding portion that is shaped as a flat plate and has a rear surface bonded to the conductive pattern, a rising portion extending upward from the bonding portion, and a joining portion that joins the bonding portion and the rising portion together without being bonded to the conductive pattern, wherein the bonding portion has, on a front surface thereof, a plurality of rows of indentations, the indentations in each row being aligned in a first direction, which is a direction from the bonding portion toward the rising portion, up to a boundary between the bonding portion and the joining portion, each of the indentations including a recess, any two of the recesses that are adjacent in a second direction, which is perpendicular to the first direction, are disposed at positions that are displaced from each other in the first direction, and each recess has a deepest point, and the deepest points of the recesses are positioned away from the boundary.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 depicts one example of a bonded part of a terminal in a semiconductor device;

FIG. 2 depicts examples of indentations formed in a front surface of a bonding portion;

FIG. 3 depicts one example of a cyclical pattern of indentation rows according to an embodiment;

FIG. 4 depicts one example of the depth of an indentation formed at a boundary in the present embodiment;

FIG. 5 depicts one example of the cyclical pattern of indentation rows in a comparative example;

FIG. 6 depicts one example of the depth of an indentation formed at a boundary according to this comparative example;

FIG. 7 depicts one example of the thickness of the bonding portion;

FIG. 8 is a graph depicting one example of the relationship between a ratio of the thickness of the bonding portion to the thickness of a non-bonding portion and the breaking load;

FIG. 9 depicts one example of the width of the bonding portion;

FIG. 10 depicts one example of the relationship between the width of the bonding portion and the breaking load;

FIG. 11 is a side view of a tool;

FIG. 12 is a cross-sectional view of a bonding tip portion of the tool;

FIG. 13 depicts an example configuration of a semiconductor device; and

FIG. 14 is a flowchart of a method of manufacturing a semiconductor device.

### DETAILED DESCRIPTION OF THE INVENTION

An embodiment will be described below with reference to the accompanying drawings. Note that, in this specification and the appended drawings, structural elements that have substantially the same function have been assigned the same reference numerals, and duplicated description of such structural elements may be omitted. In the following description, the expressions “front surface” and “upper surface” refer to a plane that faces upward in the drawings. In the same way, “up” refers to an upward direction in the drawings. The expressions “rear surface” and “lower surface” refer to a plane that faces downward in the drawings. In the same way, “down” refers to the downward direction in the drawings. The expressions “front surface”, “upper surface”, “up”, “rear surface”, “lower surface”, and “down” are merely convenient expressions used to specify relative positional relationships, and do not limit the technical scope of the present embodiment.

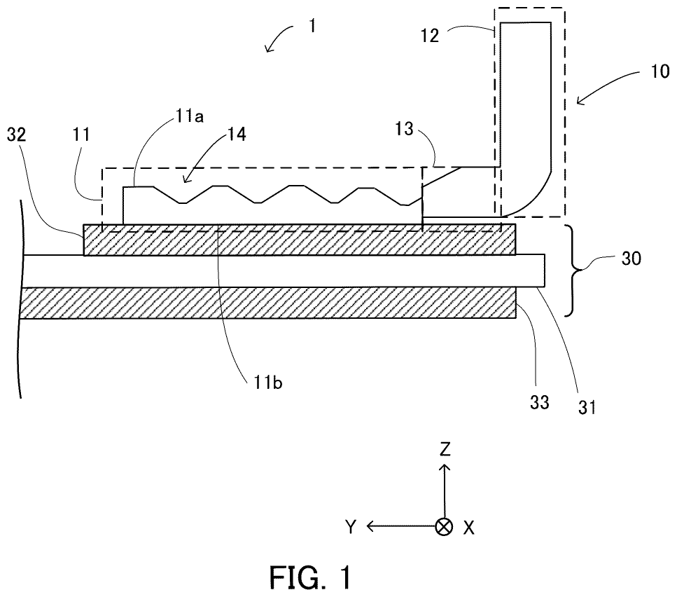

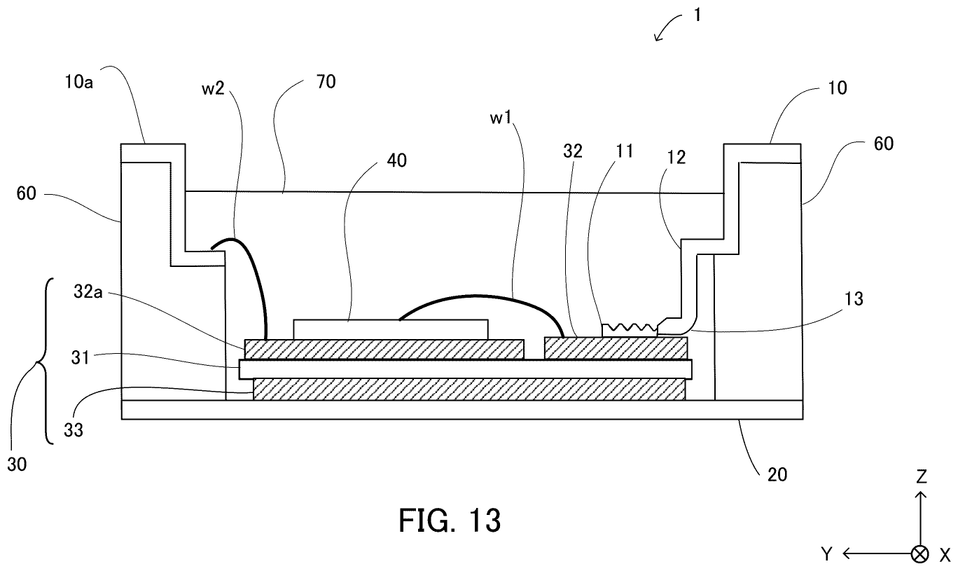

FIG. 1 depicts one example of a bonded part of a terminal in a semiconductor device. A semiconductor device 1 includes a heat dissipating plate 20 and an insulated circuit board 30 provided on the heat dissipating plate 20 (please refer to FIG. 13). The insulated circuit board 30 includes an insulating plate 31, a conductive pattern 32 formed on a front surface of the insulating plate 31, and a metal plate 33 formed on a rear surface of the insulating plate 31. The terminal 10 is bonded to the conductive pattern 32 by ultrasonic bonding.

The terminal 10 integrally includes a bonding portion 11, a rising portion 12, and a joining portion 13. The bonding portion 11 is shaped as a flat plate and in plan view includes a front surface 11a and a rear surface 11b. The rising portion 12 is formed to extend upward from the bonding portion 11. The joining portion 13 is not bonded to the conductive pattern 32 and joins the bonding portion 11 and the rising portion 12 together.

When the terminal 10 is bonded to the conductive pattern 32 by ultrasonic bonding, first, the rear surface 11b of the bonding portion 11 is disposed at a predetermined position on the conductive pattern 32. A bonding tip portion of an ultrasonic bonding tool is then placed in contact with the front surface 11a of the bonding portion 11. A plurality of protrusions are provided on this bonding tip portion, and by applying pressure to the front surface 11a of the bonding portion 11 with the bonding tip portion on which the plurality of protrusions are provided while vibrating the bonding tip portion in a designated direction, the rear surface 11b is bonded to the conductive pattern 32 (the configuration of the bonding tip portion of the tool will be described later). By performing ultrasonic bonding, indentation rows, which include a plurality of indentations 14 which include recesses, are formed in the front surface 11a of the bonding portion 11.

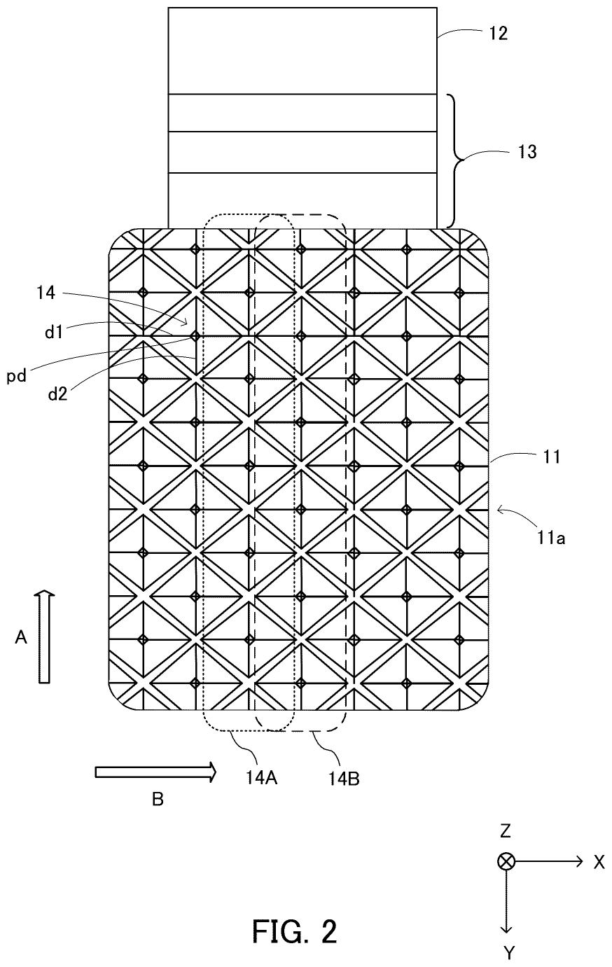

FIG. 2 depicts examples of indentations formed in the front surface of a bonding portion. The indentations 14 may be integrally formed on the front surface 11a of the bonding portion 11. Each indentation 14 includes a recess, which is formed by pressing with a protrusion in the shape of a quadrangular pyramid on the bonding tip portion of the tool, making each indentation 14 quadrangular in shape in plan view. In each indentation 14, the deepest point pd of the recess is located near the intersection of diagonals d1 and d2 of the quadrangular shape.

Indentation rows including a plurality of the indentations 14 have a cyclical (i.e., repeating) pattern, with indentation rows in a first direction (or “A direction”) from the bonding portion 11 toward the rising portion 12 and indentation rows in a second direction (or “B direction”) that is perpendicular to the first direction forming a cyclical arrangement. In addition, the recesses in indentation rows that are adjacent in the B direction are disposed at positions that are respectively shifted in the A direction so that the plurality of indentation rows are staggered. That is, as depicted in FIG. 2, the indentation row 14A and the indentation row 14B form a staggered arrangement.

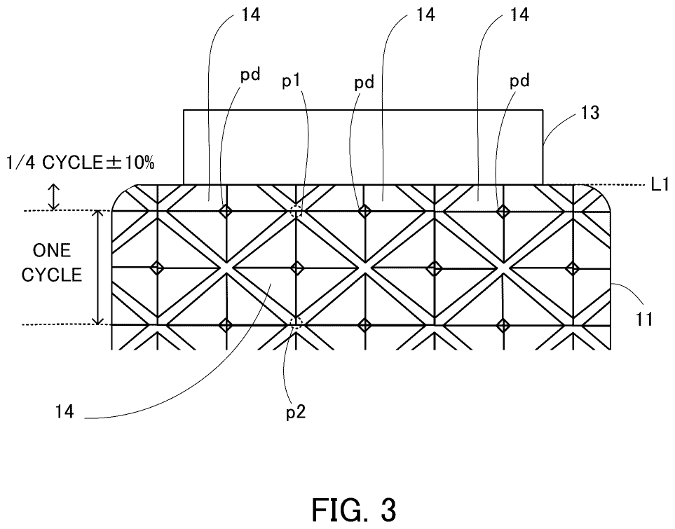

FIG. 3 depicts one example of a cyclical pattern of indentation rows according to the present embodiment. The cyclical pattern of the indentation rows according to the present embodiment is a cyclical pattern that stops midway during one cycle at a boundary L1 between the bonding portion 11 and the joining portion 13. In the example depicted in FIG. 3, when the interval between a first apex p1 and a second apex p2 of one indentation 14 is regarded as one cycle, the deepest points pd of the recesses in the indentations 14 located closest to the boundary L1 are located at positions displaced by ¼ cycle ±10% from the boundary L1.

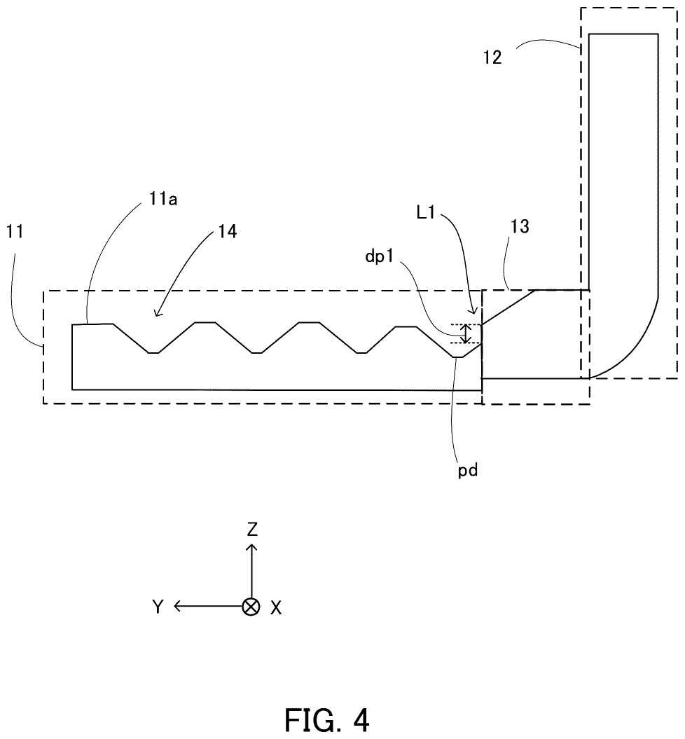

FIG. 4 depicts one example of the depth of an indentation formed at a boundary in the present embodiment. FIG. 4 is a cross-sectional view of a terminal taken along the A direction so as to pass through the deepest points. Since the deepest points pd of the recesses of the indentations 14 are displaced by ¼ cycle ±10% from the boundary L1, a deepest point pd will not be formed at the boundary L1 itself and instead a recess with a depth dp1 that is shallower than the deepest point pd is formed.

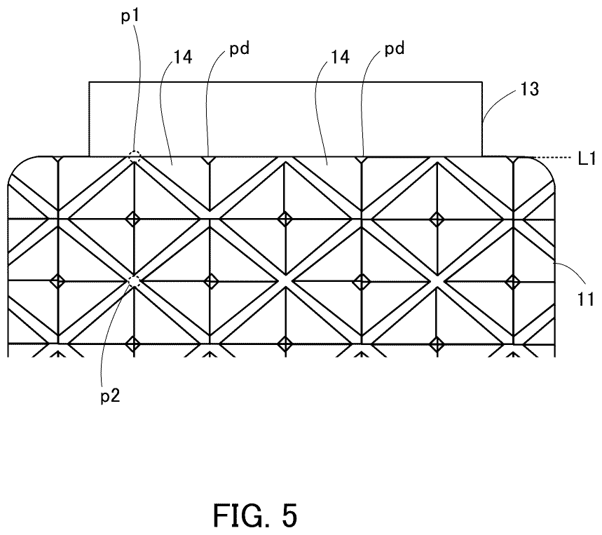

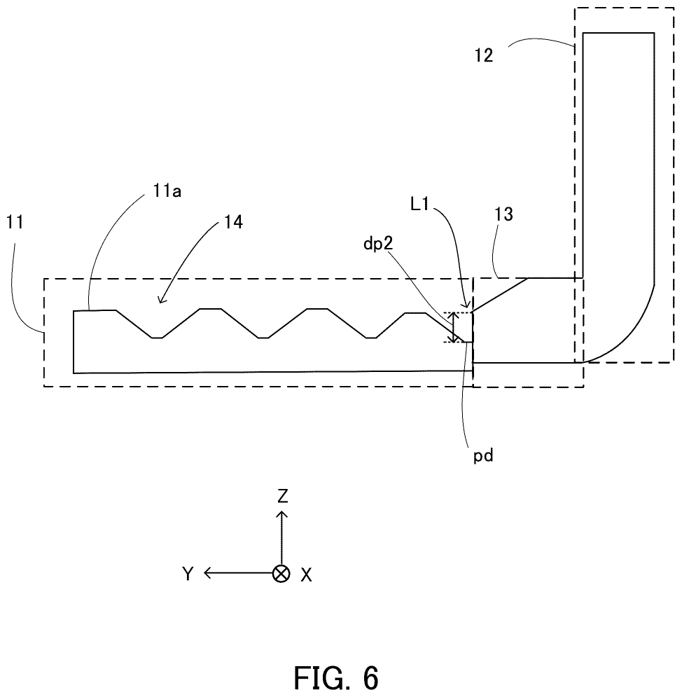

Next, the cyclical pattern of indentation rows of a comparative example will be described with reference to FIGS. 5 and 6. FIG. 5 depicts one example of the cyclical pattern of indentation rows in a comparative example. The cyclical pattern of the indentation rows in this comparative example is a cyclical pattern where a cycle of the indentation rows starts at the boundary L1. In this case, the deepest points pd of the recesses of the indentations 14 will be located at the boundary L1.

FIG. 6 depicts one example of the depth of an indentation formed at a boundary according to this comparative example. Since the deepest points pd of the recesses of the indentations 14 are located at the boundary L1, recesses with a depth dp2 are formed at the boundary L1 by the indentations 14.

Here, in the indentation rows of the comparative example with the cyclical pattern depicted in FIGS. 5 and 6, the deepest points pd of the recesses of the indentations 14 are located at the boundary L1 between the bonding portion 11 and the joining portion 13 (which may be referred to hereinafter as the “terminal neck portion”). This makes it easier for stress to be concentrated at a terminal that has been ultrasonically bonded, and since the thickness of the terminal neck portion, which tends to be where the starting points of cracks are located, is small, the terminal neck portion will be less resistant to breaking when a load is applied to the rising portion 12.

On the other hand, with the indentation rows according to the present embodiment with the cyclical pattern depicted in FIGS. 3 and 4, since the deepest points pd of the recesses of the indentations 14 are located at positions away from the terminal neck portion, the depth dp1 formed at the terminal neck portion is shallower than the depth dp2 in the comparative example. This reduces the stress produced at the terminal neck portion when a load is applied to the rising portion 12 compared with the comparative example, which results in greater resistance to breaking compared with the comparative example.

As one example, simulation results were obtained where the stress at the terminal neck portion with the present embodiment reached a maximum of 0.7 compared with a maximum stress of 1 with the comparative example, which means that the stress produced at the terminal neck portion when a load is applied to the rising portion 12 is alleviated by 30% in the present embodiment compared with the configuration of the comparative example. As described above, with the terminal 10 according to the present embodiment, when the terminal 10 is bonded to the conductive pattern 32 by ultrasonic bonding, the positions of the deepest points pd of the recesses of the indentations 14 formed on the front surface 11a of the bonding portion 11 are displaced from the boundary L1, which makes it possible to suppress the occurrence of cracks in the terminal and to improve the lifespan of products.

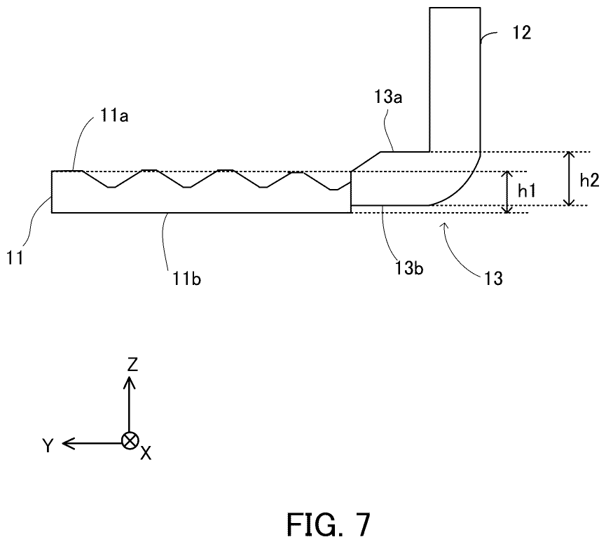

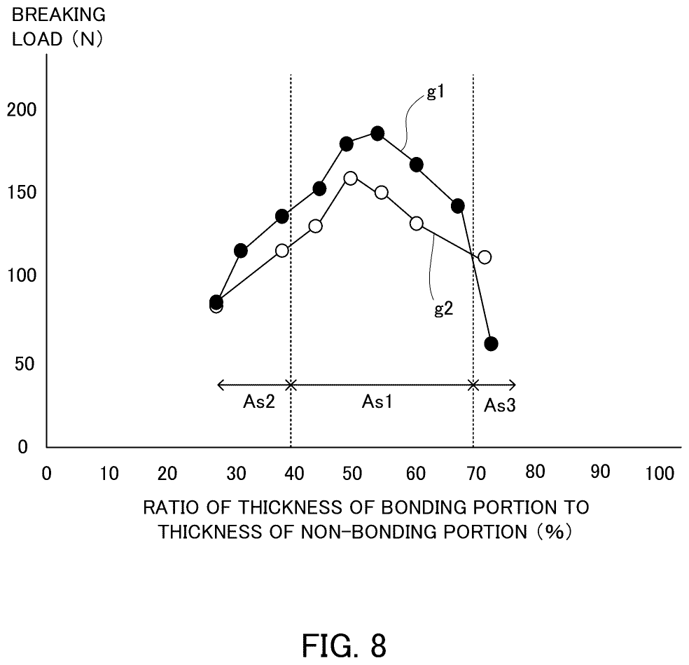

Next, the thickness of the bonding portion 11 will be described with reference to FIGS. 7 and 8. FIG. 7 depicts one example of the thickness of the bonding portion. The thickness of the terminal before bonding is set at 0.8 mm and the width at 1.6 mm. The joining portion 13 has a first non-bonding surface 13a, which is positioned on the same side as the front surface 11a of the bonding portion 11 and is parallel to the front surface 11a, and a second non-bonding surface 13b, which is positioned on the same side as the rear surface 11b of the bonding portion 11 and is parallel to the rear surface 11b.

The height (thickness) h1 from the rear surface 11b to the shallowest part of an indentation in the front surface 11a of the bonding portion 11 is 0.4 to 0.7 times the height h2 from the second non-bonding surface 13b to the first non-bonding surface 13a of the joining portion 13. Note that since the first non-bonding surface 13a is a part that is not pressed by the tool, the height h2 is equal to the thickness of the terminal before bonding.

FIG. 8 is a graph depicting one example of the relationship between the ratio of the thickness of the bonding portion to the thickness of the non-bonding portion and the breaking load. The horizontal axis represents the ratio (%) of the thickness of the bonding portion to the thickness of the non-bonding portion, and the vertical axis represents the breaking load (N) at the terminal neck portion. The ratio of the bonding portion thickness to the non-bonding portion thickness is the parameter h1/h2. Since the breaking load indicates an index of a load at which breakage or delamination occurs when a load is applied to the terminal in a direction that is perpendicular to a bonding surface, as the breaking load increases, breakage or delamination becomes less likely to occur.

The line g1 indicates the breaking load for a case where the terminal 10 is bonded to the conductive pattern 32 using a substrate where Al₂O₃ is used for the insulating plate 31. The line g2 indicates the breaking load for a case where the terminal 10 is bonded to the conductive pattern 32 using a substrate where AlN is used for the insulating plate 31.

The section marked as As1 indicates the range of parameters for a case where the height ratio (h1/h2) is 0.4 to 0.7 times. The section marked as As2 indicates a range of parameters that are smaller than the parameters in the section As1, and the section marked as As3 indicates a range of parameters that are larger than the parameters in the section As1.

Here, the breaking loads included in the range of parameters in the section As2 are smaller for both the lines g1 and g2 than the breaking loads included in the range of parameters in the section As1. The breaking loads included in the range of parameters in the section As3 are smaller for both the lines g1 and g2 than the breaking loads included in the range of parameters in the section As1.

When the thickness of the bonding portion 11 is reduced, the stress produced at the terminal neck portion when evaluating the breaking load increases, making the terminal susceptible to breaking and reducing the breaking load. When the thickness of the bonding portion 11 is increased, the stress generated at the bonding interface during the bonding process falls, which prevents sufficient bonding from being performed, thereby reducing the bonding strength and reducing the breaking load.

Accordingly, by setting the ratio (h1/h2) of the height h1 from the rear surface 11b to the front surface 11a of the bonding portion 11 to the height h2 from the second non-bonding surface 13b to the first non-bonding surface 13a of the joining portion 13 within the range of the section As1, that is, 0.4 to 0.7 times, it is possible to maintain the bonding strength while suppressing the occurrence of breakages.

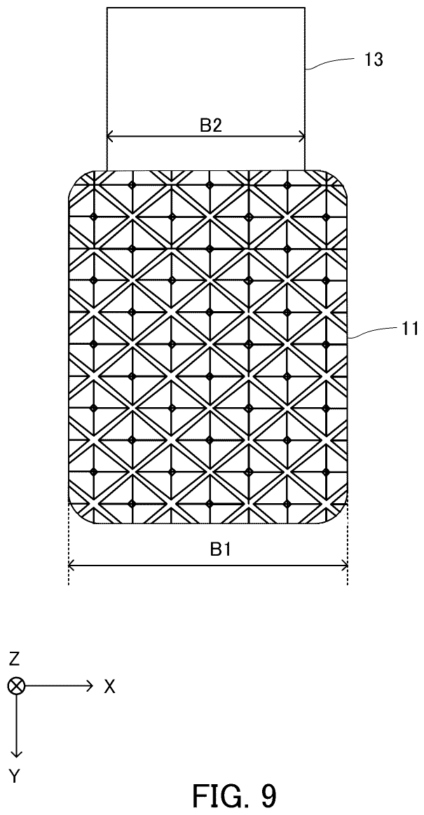

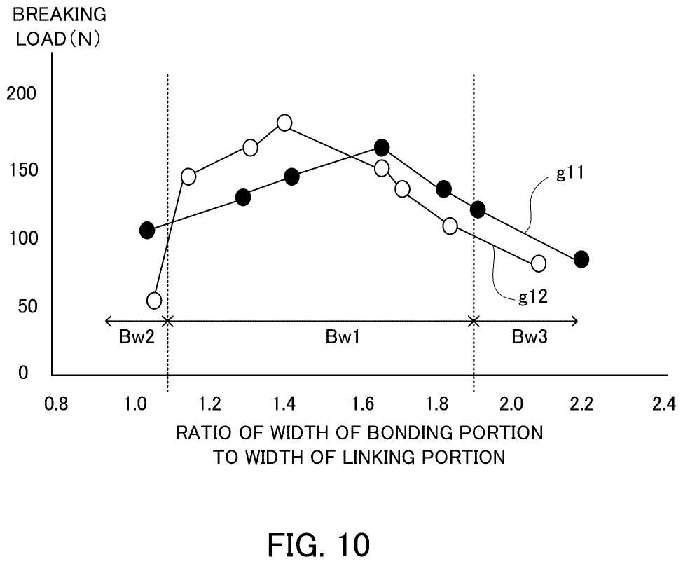

Next, the width of the bonding portion 11 will be described with reference to FIGS. 9 and 10. FIG. 9 depicts one example of the width of the bonding portion. FIG. 10 depicts one example of the relationship between the width of the bonding portion and the breaking load. The horizontal axis represents the ratio (B1/B2) of the width B1 of the bonding portion 11 to the width B2 of the joining portion 13, and the vertical axis represents the breaking load (N) at the terminal neck portion.

The line g11 indicates the breaking load for a case where the terminal 10 is bonded to the conductive pattern 32 using a substrate where Al₂O₃ is used for the insulating plate 31. The line g12 indicates the breaking load for a case where the terminal 10 is bonded to the conductive pattern 32 using a substrate where AlN is used for the insulating plate 31.

The section marked as Bw1 indicates a range where the width ratio (B1/B2) is 1.1 to 1.9 times. The section marked as Bw2 indicates a range where the width ratio is smaller than the width ratio (B1/B2) in the section Bw1, and the section marked as Bw3 indicates a range where the width ratio is larger than the width ratio (B1/B2) in the section Bw1.

Here, the breaking loads included in the range of the width ratio (B1/B2) in the section Bw2 are smaller for both the lines g11 and g12 than the breaking loads included in the range of the width ratio (B1/B2) in the section Bw1. The breaking loads included in the range of the width ratio (B1/B2) in the section Bw3 are smaller for both the lines g11 and g12 than the breaking loads included in the range of the width ratio (B1/B2) in the section Bw1.

A region where the width B1 of the bonding portion 11 is small corresponds to the region where the parameter in FIG. F 8 is large, and since the stress generated at the bonding interface during the bonding process is low, there is a reduction in bonding strength and a reduction in the breaking load. A region where the width B1 of the bonding portion 11 is large corresponds to the region where the parameter in FIG. 8 is small, so that although the bonding area on the conductive pattern is large, the terminal neck portion becomes thinner, which increases the stress produced when evaluating the breaking load and makes the terminal susceptible to breaking, which reduces the breaking load.

Accordingly, by setting the ratio (B1/B2) of the width B1 of the bonding portion 11 to the width B2 of the joining portion 13 within the range of the section Bw1, that is, 1.1 to 1.9 times, it is possible to maintain the bonding strength while suppressing the occurrence of breakages.

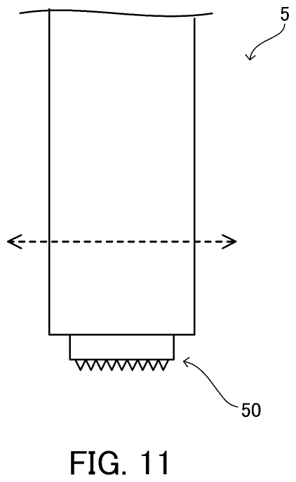

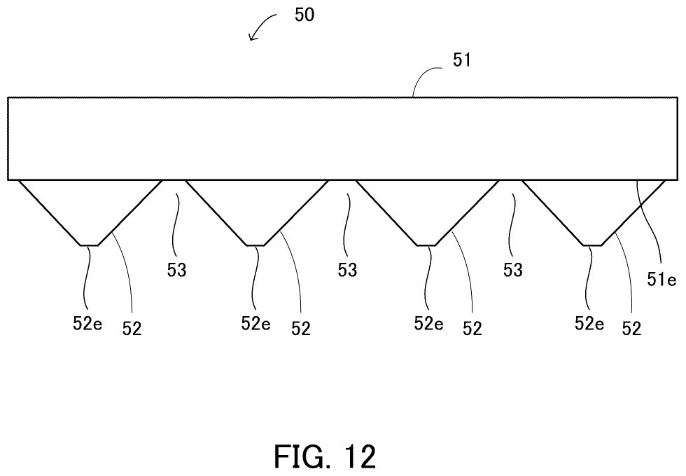

Next, a tool included in the ultrasonic bonding apparatus will be described with reference to FIGS. 11 and 12. FIG. 11 is a side view of the tool. A tool 5 is included in an ultrasonic bonding apparatus. The tool 5 is columnar in shape and is vibrated in a predetermined direction, which is indicated by the dotted arrow in the drawing, by a vibration generator included in the ultrasonic bonding apparatus. The columnar shape may be either a circular column or a polygonal column. The tool 5 includes a bonding tip portion 50 at the front end. The bonding tip portion 50 is placed in contact with a bonded object and presses and bonds the bonded object while vibrating in the designated direction.

FIG. 12 is a cross-sectional view of the bonding tip portion of the tool. The bonding tip portion 50 includes a bonding substrate 51 and a plurality of protrusions 52. The bonding substrate 51 and the plurality of protrusions 52 included in the bonding tip portion 50 may be made of the same material. One example of such material is a superhard alloy. Examples of superhard alloys include tungsten, tungsten carbide, and an alloy containing at least one of these.

The bonding substrate 51 is located at the front end of the bonding tip portion 50 that is placed in contact with the bonded object. The bonding substrate 51 is rectangular in shape in plan view, and includes a flat front end surface 51e that is substantially parallel to the X-Z plane and side surfaces that surround all four sides of the front end surface 51e. The plurality of protrusions 52 are provided on this front end surface 51e and are arranged with gaps 53 in between. The plurality of protrusions 52 may be integrally formed on the front end surface 51e. That is, the front end surface 51e of the bonding substrate 51 includes a collection of convexes and concaves formed by the plurality of protrusions 52. Each protrusion 52 is shaped as a quadrangular pyramid and includes a flat pressing surface 52e at the apex of the pyramid. When the protrusions 52 are pressed against a bonded object, these pressing surfaces 52e form the deepest points mentioned earlier.

The height of the plurality of protrusions 52 from the front end surface 51e to the pressing surfaces 52e is 15% or more and 90% or less of the thickness of the bonded object. In cases where the height of the plurality of protrusions 52 from the front end surface 51e is less than 15% of the thickness of the bonded object, when bonding is performed by a bonding tip portion 50 including a plurality of protrusions 52 of this size, the bonded object will become abraded and damaged. In cases where the height of the plurality of protrusions 52 from the front end surface 51e exceeds 90% of the thickness of the bonded object, there is the risk of the bonded object breaking. In the present embodiment, the height of the plurality of protrusions from the front end surface 51e 52 to the pressing surfaces 52e is 0.15 mm or more, for example.

Here, out of the plurality of protrusions 52 provided on the bonding tip portion 50 of the tool 5, the protrusions 52 located at end portions of the bonding substrate 51 and the protrusions 52 located in the central portion of the bonding substrate 51 all have the same shape. In the present embodiment, the tool 5 including the plurality of protrusions 52 with the same shape is used to press the protrusions 52 against the front surface 11a of the bonding portion 11 of the terminal 10 so that the positions of the deepest points of the recesses in the indentations are displaced from the boundary L1.

By using the same shape for the plurality of protrusions 52 provided on the bonding tip portion 50 of the tool 5, the pressing action will be uniform up to the end portions of the bonding substrate 51, making it possible to uniformly increase the bonded area. In addition, although some cracking the bonding of interface will occur from the end portions of the bonding substrate 51 as a form of deterioration during device operation, the achievement of uniform bonding strength up to the end portions of the bonding substrate 51 delays the propagation of any such cracking. Also, by making it possible to perform various types of terminal bonding using a tool in which the plurality of protrusions 52 have the same shape, the bonding process is simplified and there is greater design freedom regarding the width, depth, and thickness of the terminal material.

FIG. 13 depicts an example configuration of a semiconductor device and is a cross-sectional view of the semiconductor device 1 in which the terminal 10 with the indentation rows described earlier is used. The semiconductor device 1 includes the insulated circuit board 30, terminals 10 and 10a bonded to the front surface of the insulated circuit board 30, the heat dissipating plate 20, and a semiconductor chip 40.

The insulated circuit board 30 includes the insulating plate 31, conductive patterns 32 and 32a, and the metal plate 33. When the conductive patterns 32 and 32a and the metal plate 33 are copper foil patterns, for example, it is possible to use a DCB substrate where the conductive patterns 32 and 32a and the metal plate 33 are directly bonded to both sides of the insulating plate 31. The insulated circuit board 30 is mounted on the upper surface of the heat dissipating plate 20, and the terminal 10 provided on the case 60 is bonded onto the conductive pattern 32 of the insulated circuit board 30 by ultrasonic bonding.

On the other hand, the semiconductor chip 40 is bonded onto the conductive pattern 32a via a bonding material. A wire w1 connects an electrode of the semiconductor chip 40 and the conductive pattern 32 that serves as a lead electrode of the insulated circuit board 30. A wire w2 connects the conductive pattern 32a and a terminal 10a provided on the case 60. The wires w1 and w2 are bonded by wire bonding using ultrasound and a load.

As one example, the wires w1 and w2 are made of an electrically conductive metal, such as copper or aluminum, or an electrically conductive alloy such as an iron-aluminum alloy, and are formed with a diameter of 300 to 500 μm, for example, in a high-voltage device.

The insulated circuit board 30 to which the semiconductor chip 40 is bonded is housed in the case 60, and a region surrounded by the case 60 and the heat dissipating plate 20 is filled and encapsulated with encapsulating resin 70. The case 60 and the heat dissipating plate 20 are fixed using adhesive or the like.

Here, as one example, the insulating plate 31 of the insulated circuit board 30 is an electrically insulating ceramic, such as aluminum nitride, silicon nitride, or aluminum oxide, and as one example is a plate-like member with a thickness of 0.2 to 1 mm.

On the other hand, the conductive patterns 32 and 32a of the insulated circuit board 30 are provided on the front surface of the insulating plate 31 and are made of a material with superior electrical conductivity. Example materials include copper, aluminum, and an alloy containing at least one of these metals. The thickness of the conductive patterns 32 and 32a is 0.2 mm or 0.3 mm, for example.

In addition to the semiconductor chip 40, wiring members, such as bonding wires, lead frames, and connection terminals, and electronic components may be appropriately disposed as needed on the conductive patterns 32 and 32a.

The number, arranged positions, and shapes of the conductive patterns 32 and 32a may be appropriately selected during the design process. The metal plate 33 of the insulated circuit board 30 is made of an electrically conductive metal, such as copper or aluminum, and is provided on the rear surface of the insulating plate 31 with a thickness of 0.1 to 1 mm, for example.

As the heat dissipating plate 20, a copper substrate, an aluminum silicon carbide composite (Al—SiC) substrate, or the like that favorably dissipates heat may be used for example. The semiconductor chip 40 is a power device made of silicon, silicon carbide, or gallium nitride. The semiconductor chip 40 includes a switching element. The switching element is a power metal-oxide-semiconductor field-effect transistor (MOSFET), an insulated gate bipolar transistor (IGBT), or the like.

As one example, the semiconductor chip 40 includes a drain electrode (a positive electrode, and in the case of an IGBT, the collector electrode) as a main electrode, a gate electrode as a control electrode, and a source electrode (a negative electrode, and in the case of an IGBT, the emitter electrode) as another main electrode.

The semiconductor chip 40 also includes a diode element. One example of this diode element is a free wheeling diode (FWD), such as a Schottky barrier diode (SBD) or a P-intrinsic-N (PiN) diode.

Other electronic components may be disposed as needed on the conductive patterns 32 and 32a. Examples of such electronic components include a capacitor, a resistor, a thermistor, a current sensor, and a control integrated circuit (IC). The solder used as the bonding material is resistant to the generation of voids and is resistant to high temperatures. One example of such solder is an alloy with tin and antimony as main components. As one example, gel filler may be used as the encapsulating resin 70.

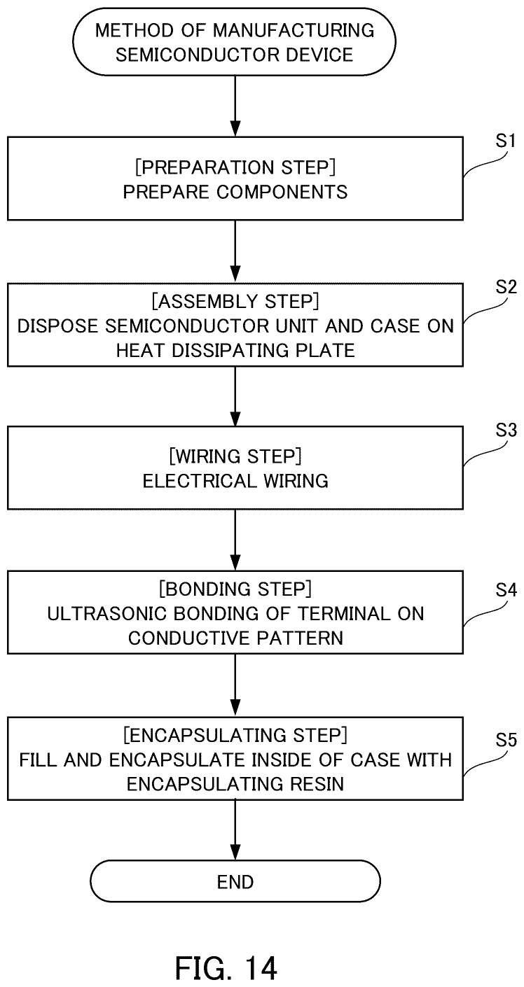

FIG. 14 is a flowchart of a method of manufacturing a semiconductor device. This method of manufacturing the semiconductor device 1 includes a preparation step, an assembly step, a wiring step, a bonding step, and an encapsulating step.

[Step S1] A preparation step of preparing the components that form the semiconductor device 1 and manufacturing equipment used for manufacturing is performed. As one example, the components of the semiconductor device 1, such as the semiconductor chip 40, the insulated circuit board 30 including the conductive patterns 32 and 32a, the heat dissipating plate 20, the case 60, the encapsulating resin 70, and the terminal 10, are prepared.

The semiconductor chip 40 is bonded to the insulated circuit board 30, and a lead frame is further bonded to assemble a semiconductor unit. Equipment used in the method of manufacturing the semiconductor device 1 is also prepared. Examples of such equipment include an ultrasonic bonding device including the tool 5, a wire bonding device, and a dispenser device for the encapsulating resin. Other components and equipment aside from those described above may also be prepared as needed.

[Step S2] An assembly process is performed in which the semiconductor unit is bonded to the heat dissipating plate 20 and the case 60 is disposed on the heat dissipating plate 20.

[Step S3] A wiring step of wiring the semiconductor unit is performed. In this wiring step, the terminals and semiconductor the unit are electrically wired using wiring members (the wires w1, w2, and the like).

[Step S4] A bonding step of bonding the terminal 10 to the conductive pattern 32 of the insulated circuit board 30 is performed. In this bonding step, the rear surface 11b of the bonding portion 11 is disposed on the conductive pattern 32, and the front surface 11a of the bonding portion 11 is pressed while being vibrated by the tool 5 which includes the pressing surfaces that are quadrangular in shape and formed on protrusions near intersections of diagonals.

Indentation rows including a plurality of indentations 14 with recesses are formed by the plurality of protrusions 52 on the front surface 11a of the bonding portion 11 up to the boundary between the bonding portion 11 and the joining portion 13, which bonds the rear surface 11b of the bonding portion 11 to the conductive pattern 32. When doing so, the protrusions are pressed onto the front surface 11a of the bonding portion 11 so that the positions of the deepest points in the recesses of the indentations 14 are displaced from the boundary between the bonding portion 11 and the joining portion 13.

When the terminal 10 is pressed by the tool 5, the terminal 10 deforms until the height from the rear surface 11b to the front surface 11a of the bonding portion 11 becomes 0.4 to 0.7 times the height from the second non-bonding surface 13b to the first non-bonding surface 13a of the joining portion 13. The bonding portion 11 also deforms until the width of the bonding portion 11 becomes 1.1 to 1.9 times the width of the joining portion 13.

[Step S5] An encapsulating step is performed in which the unit housing portion of the case 60, in which the semiconductor unit is housed, is filled and encapsulated with the encapsulating resin 70.

According to the above aspect, it is possible to suppress the occurrence of cracks in a terminal.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor apparatus, comprising:
a conductive pattern; and
a terminal, including:
a bonding portion that is shaped as a flat plate and has a rear surface bonded to the conductive pattern,
a rising portion extending upward from the bonding portion, and
a joining portion that joins the bonding portion and the rising portion together without being bonded to the conductive pattern, wherein
the bonding portion has, on a front surface thereof, a plurality of rows of indentations, the indentations being aligned in a first direction, which is a direction from the bonding portion toward the rising portion, up to a boundary between the bonding portion and the joining portion, each of the indentations including a recess,
any two of the recesses that are adjacent in a second direction, which is perpendicular to the first direction, are disposed at positions that are displaced from each other in the first direction, and
each recess has a deepest point, and the deepest points of the recesses are positioned away from the boundary.

2. The semiconductor device according to claim 1, wherein
the plurality of rows of indentations are positioned to form a cyclical pattern, in which each indentation is of a quadrangular shape in a top view thereof, with the deepest point of the recess thereof positioned adjacent to an intersection of diagonals of the quadrangular shape, and
the positions of the deepest points of the recesses that are closest to the boundary are away from the boundary by ¼ cycle ±10%.

3. The semiconductor device according to claim 1,
wherein the plurality of rows of indentations are positioned to form a cyclical pattern, in which each indentation is of a quadrangular shape in a top view thereof, with the deepest point thereof positioned adjacent to an intersection of diagonals of the quadrangular shape, and
the plurality of rows of indentations are in a staggered arrangement.

4. The semiconductor device according to claim 1, wherein
the joining portion includes:
a first non-bonding surface, which is parallel to the front surface of the bonding portion, and is located on a side of the joining portion facing a third direction, which is a direction from the rear surface to the front surface of the bonding portion, and
a second non-bonding surface, which is parallel to the rear surface of the bonding portion, and is located opposite to the first non-bonding surface in the third direction, and
in the third direction, a height from the rear surface to a shallowest part of the indentations in the front surface of the bonding portion is 0.4 to 0.7 times a height from the second non-bonding surface to the first non-bonding surface of the joining portion.

5. The semiconductor device according to claim 1,
wherein a width of the bonding portion is 1.1 to 1.9 times a width of the joining portion.

6. A method of manufacturing a semiconductor device, comprising:
preparing a conductive pattern and a terminal, the terminal including:
a bonding portion that is shaped as a flat plate and has a rear surface to be bonded to the conductive pattern,
a rising portion extending upward from the bonding portion, and
a joining portion that joins the bonding portion and the rising portion together without being bonded to the conductive pattern;
providing a tool having a plurality of pressing surfaces, each of which is of a quadrangular shape, and has a protrusion formed adjacent to an intersection of diagonals of the quadrangular shape; and
bonding the rear surface of the bonding portion to the conductive pattern by disposing the rear surface of the bonding portion on the conductive pattern, pressing the front surface of the bonding portion with the tool while vibrating the tool to form, with the protrusions, a plurality of rows of indentations, the indentations in each row being aligned in a first direction, which is a direction from the bonding portion toward the rising portion, on the front surface of the bonding portion up to a boundary between the bonding portion and the joining portion, wherein
the indentations so formed each include a recess,
each recess has a deepest point, and
the deepest points of the recesses are positioned away from the boundary.

7. The method of manufacturing a semiconductor device according to claim 6, wherein the front surface of the bonding portion is so pressed that
the plurality of rows of indentations formed thereby are positioned to form a cyclical pattern, in which each indentation is of the quadrangular shape, with the deepest point of the recess thereof positioned adjacent to the intersection of diagonals of the quadrangular shape, and
the positions of the deepest points of the recesses that are closest to the boundary are away from the boundary by ¼ cycle ±10%.

8. The method of manufacturing a semiconductor device according to claim 6, wherein the front surface of the bonding portion is so pressed that
the plurality of rows of indentations formed thereby are positioned to form a cyclical pattern, in which each indentation is of the quadrangular shape, with the deepest point of the recess thereof positioned adjacent to the intersection of diagonals of the quadrangular shape, and
the plurality of rows of indentations are in a staggered arrangement.

9. The method of manufacturing a semiconductor device according to claim 6, wherein
the joining portion includes:
a first non-bonding surface, which is parallel to the front surface e of the bonding portion, and is located on a side facing a third direction, which is a direction from the rear surface to the front surface of the bonding portion, and
a second non-bonding surface, which is parallel to the rear surface of the bonding portion, and is located opposite to the first non-bonding surface in the third direction, and
by pressing the front surface of the bonding portion with the tool, the bonding portion deforms until in the thickness direction, a height from the rear surface to a shallowest part of the indentations in the front surface of the bonding portion becomes 0.4 to 0.7 times a height from the second non-bonding surface to the first non-bonding surface of the joining portion.

10. The method of manufacturing a semiconductor device according to claim 6,
wherein by pressing the front surface of the bonding portion with the tool, the bonding portion deforms until a width of the bonding portion becomes 1.1 to 1.9 times a width of the joining portion.
